(19) United States
(12) Patent Application Publication
(10) Pub. No.: US 2012/0176119 A1
(43) Pub. Date: Jul. 12, 2012

(54) PHASE LINE IDENTIFICATION SYSTEM AND METHOD

(75) Inventor: Hernan Alex Rojas, Smyrna, GA (US)

(73) Assignee: GENERAL ELECTRIC COMPANY, Schenectady, NY (US)

(21) Appl. No.: 12/985,414

(22) Filed: Jan. 6, 2011

(51) Int. Cl. G01R 25/00

(52) U.S. Cl. 324/66

(57) ABSTRACT

A phase line identification system including, at least one computer hardware device including: a first receiver that receives a plurality of times of a primary phase zero crossing for a plurality of primary phase lines at a feeder; a second receiver that receives a time of a secondary phase zero crossing for a secondary phase line at a single phase electric meter; a comparator that identifies which of the plurality of primary phase lines feeds the secondary phase line by comparing the plurality of times of the primary phase zero crossing for the plurality of primary phase lines at the feeder to the time of the secondary phase zero crossing of the secondary phase line at the single phase electric meter to determine which one of the plurality of times of the primary phase zero crossing matches the time of the secondary phase zero crossing.

### BACKGROUND OF THE INVENTION

This invention relates generally to electricity distribution and more particularly to a system for phase line identification of electricity distribution across an electric grid or network.

Conventionally, electricity distribution begins with generation at a generating station. From the generating station, electricity may be transmitted to a generating step-up transformer. The generating step-up transformer may subsequently transmit that electricity across transmission lines to a substation step-down transformer.

Referring to FIG. 1, a schematic diagram depicting a portion of a known electricity distribution network is illustrated. In this case, a feeder 102 at a substation step-down transformer 104 may transmit electricity through a plurality of primary phase lines 106 to a secondary customer 108, e.g., residential homes and small businesses. The plurality of primary phase lines 106 may also represent a conventional three phase system 110. The plurality of primary phase lines 106 may transmit electricity to a secondary step-down transformer 112, where secondary customer 108 taps into a secondary phase line 114. Secondary phase line 114 may receive electricity from one of the plurality of primary phase lines 106 and may be connected to single phase electric meter 116 at secondary customer 108. A plurality of primary phase lines may feed a plurality of secondary step-down transformers 112. Each secondary step-down transformer 112 may feed a plurality of secondary phase lines 114.

Efficient energy distribution may require balanced distribution of electricity in each of the plurality of primary phase lines 106. When a plurality of secondary customers 108 are set up for electrical service, each secondary phase line 114 for each secondary customer 108 taps one of plurality of primary phase lines 106.

Referring to FIG. 2, a graphical diagram depicting known phase line waveforms is shown. In FIG. 2, electrical voltage moving through each primary phase line 106 (FIG. 1) or secondary phase line 114 (FIG. 1) is illustrated as a primary phase line waveform 118 or a secondary phase line waveform 124, respectively. A frequency over a period of time of each primary phase line 106 is illustrated as a plurality of primary phase line waveforms 118. Each primary phase line 106 may be identified by a time of primary phase zero crossing 120. As is known in the art, time of primary phase zero crossing 120 represents the time when the voltage in the primary phase line 106 is approximately zero. In three phase system 110 (FIG. 1), each primary phase line 106 of the three primary phase lines 106 has a different time of primary phase zero crossing 120 (t₁, t₂, t₃) that is unique to each primary phase line 106. Similarly, this would be true for any plurality of primary phase lines 106. Similarly, each secondary phase line 114 may be identified by a time of secondary phase zero crossing 122. Each secondary phase line waveform 124 may identically match one of primary phase line waveforms 118. For illustrative purposes secondary phase line waveform 124 is shown slightly offset from one of the plurality of primary phase line waveforms 118 but, if identical, would graphically be in precisely the same place as primary phase line waveform 118.

Feeder 102 may not feed electricity through each of the plurality of primary phase lines in equal amounts. Secondary phase lines 114 may be connected to primary phase lines 106 in such a way that the demand for electricity on primary phase lines 106 is not in equal amounts. Identifying each primary phase line 106 transmitting to each secondary phase line 114 may assist in balancing the demand of electrical distribution through plurality of primary phase lines 106.

### BRIEF DESCRIPTION OF THE INVENTION

Embodiments of the invention include systems, methods, and computer program products for phase line identification.

A first aspect of the invention includes a phase line identification system, comprising: at least one computer hardware device including: a first receiver that receives a plurality of times of a primary phase zero crossing for a plurality of primary phase lines at a feeder; a second receiver that receives a time of a secondary phase zero crossing for a secondary phase line at a single phase electric meter; a comparator that identifies which of the plurality of primary phase lines feeds the secondary phase line by comparing the plurality of times of the primary phase zero crossing for the plurality of primary phase lines at the feeder to the time of the secondary phase zero crossing of the secondary phase line at the single phase electric meter to determine which one of the plurality of times of the primary phase zero crossing matches the time of the secondary phase zero crossing.

A second aspect of the invention includes a method, comprising: receiving a plurality of time of a primary phase zero crossing for a plurality of primary phase lines at a feeder; receiving a time of a secondary phase zero crossing for a secondary phase line at a single phase electric meter; identifying which of the plurality of primary phase lines feeds the secondary phase line by comparing the plurality of times of the primary phase zero crossing for the plurality of primary phase lines at the feeder to the time of the secondary phase zero crossing of the secondary phase line at the single phase electric meter to determine which one of the plurality of times of the primary phase zero crossing matches the time of the secondary phase zero crossing.

A third aspect of the invention includes a computer program product comprising program code embodied in at least one computer-readable storage medium, which when executed, enables a computer system to implement a method, the method comprising: receiving a plurality of time of a primary phase zero crossing for a plurality of primary phase lines at a feeder; receiving a time of a secondary phase zero crossing for a secondary phase line at a single phase electric meter; identifying which of the plurality of primary phase lines feeds the secondary phase line by comparing the plurality of times of the primary phase zero crossing for the plurality of primary phase lines at the feeder to the time of the secondary phase zero crossing of the secondary phase line at the single phase electric meter to determine which one of the plurality of times of the primary phase zero crossing matches the time of the secondary phase zero crossing.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a schematic diagram depicting a portion of a known electrical distribution network.

FIG. 2 shows a graphical diagram depicting known phase line waveforms associated with the electrical distribution system of FIG. 1.

FIG. 3 shows a block diagram depicting a phase line identification system in accordance with one embodiment of the invention.

FIG. 4 shows a block diagram depicting a phase line identification system in accordance with one embodiment of the invention.

FIG. 5 shows a flow diagram representing an embodiment of a method of phase identification.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

In contrast to conventional electricity distribution systems, aspects of the invention allow for comparison of phase line identifications across a plurality of secondary customers 108 receiving electricity from a plurality of primary phase lines 106 at a feeder 102 at substation step-down transformer 104 to correct imbalances in the electrical load between each primary phase line 106. Correcting imbalances in the electrical load between each primary phase line 106 may include manually changing the primary phase line 106 feeding each secondary phase line 114 for each secondary customer 108, adjusting the primary phase line 106 feed ordered for any new secondary customers 108, or any other now known or to be developed method for altering the number of secondary phase lines 114 being fed by primary phase line 106.

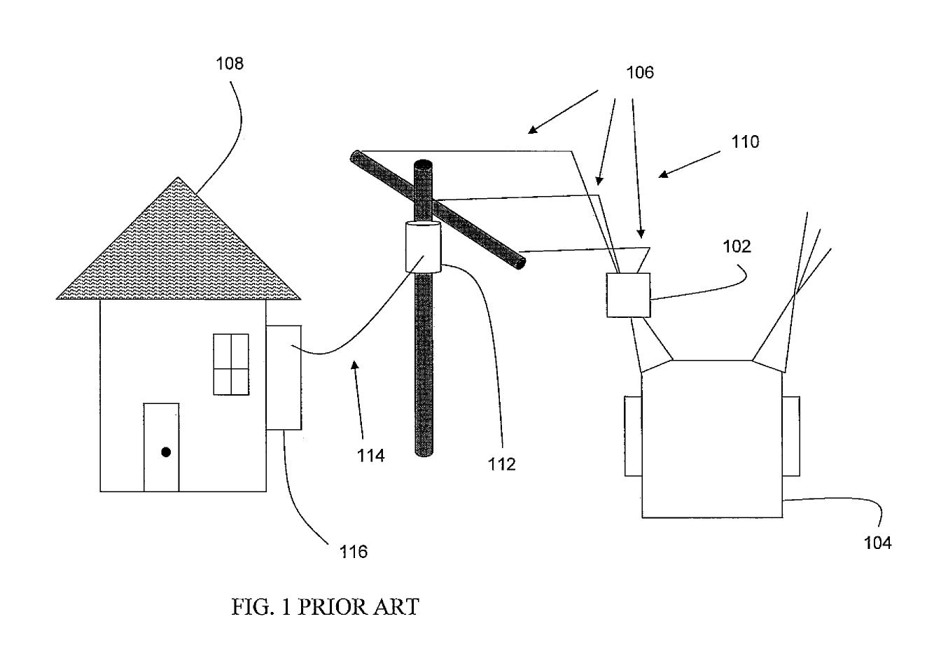

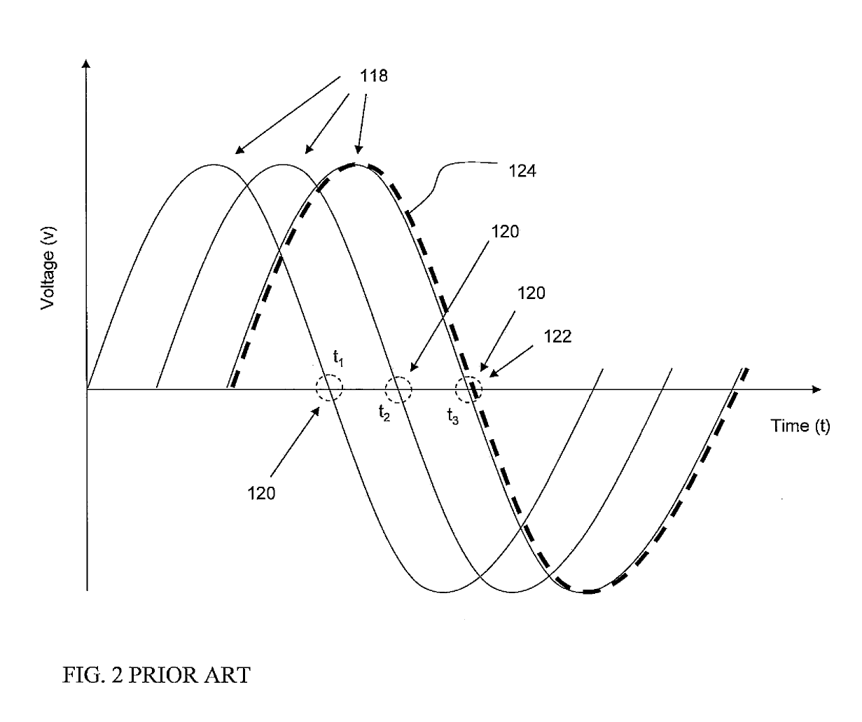

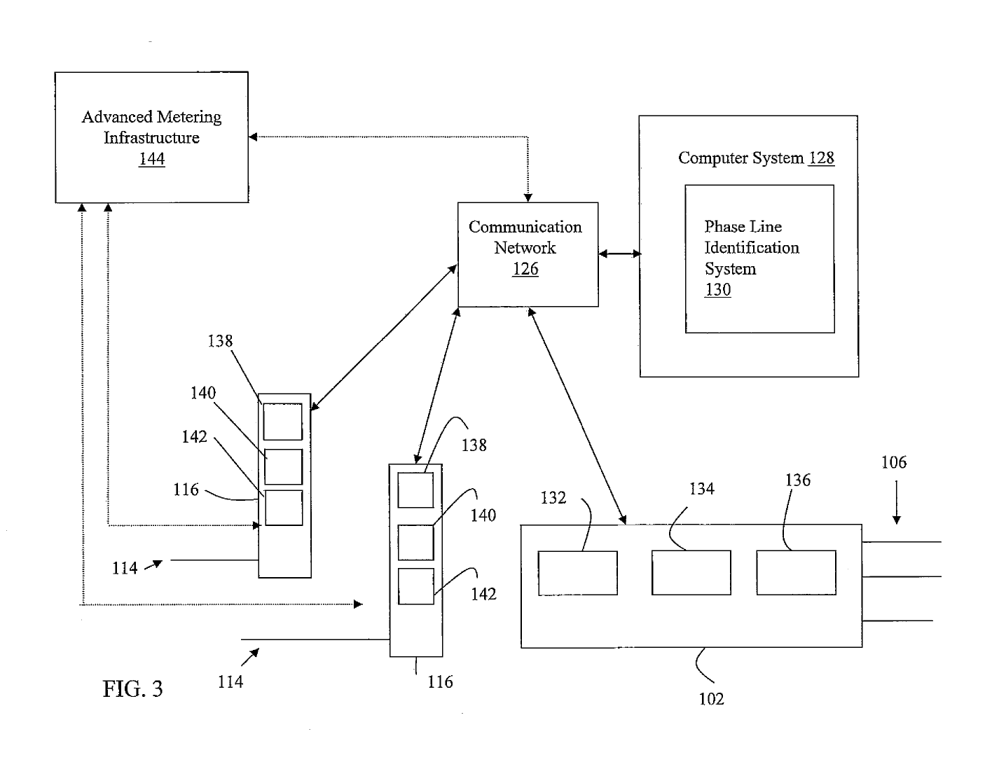

Referring to FIG. 3 a block diagram depicting a phase line identification system in accordance with one embodiment of the invention is shown. In FIG. 3, feeder 102 feeds a plurality of primary phase lines 106 and a plurality of single phase electric meters 116 are each fed by secondary phase line 114 as previously described with respect to FIG. 1. Feeder 102 is shown in communication with a communication network 126 and in turn a computer system 128 with a phase line identification system 130. Feeder 102 may include a primary phase zero-crossing sensor 132 for identifying a primary phase zero crossing for each of plurality of primary phase lines 106; a first global positioning sensor (GPS) 134 for determining a time of primary phase zero crossing 120 (FIG. 2) for each of plurality of primary phase lines 106 at feeder 102; and a first transmitter 136 for transmitting, through communication network 126, the time of primary phase zero crossing 120 (FIG. 2) for each of plurality of primary phase lines 106. It is well known to a person skilled in the art that zero crossing sensors detect the transition of a signal waveform from positive and negative providing a narrow pulse that coincides exactly with the zero voltage condition. It is well known to a person skilled in the art that global positioning systems provide reliable location and time information anywhere on the earth providing there is an unobstructed line of sight to four or more global positioning system satellites. Communication network 126 may include any conventional components for transmitting data, e.g. internet, cables, radios, etc. Transmitting may be performed by any now known or to be developed method such as, for example, cable transmission and radio transmission.

Continuing with FIG. 3, a plurality of single phase electric meters 116 are shown in communication with communication network 126 and in turn computer system 128 having phase line identification system 130. Each single phase electric meter 116 may include a secondary phase zero-crossing sensor 138 for identifying a secondary phase zero crossing for secondary phase line 114; a second GPS 140 for determining a time of secondary phase zero crossing 122 (FIG. 2) for secondary phase line 114 at single phase electric meter 116; and a second transmitter 142 for transmitting, through communication network 126, the time of secondary phase zero crossing 122 for secondary phase line 114 to phase line identification system 130. Each single phase electric meter 116 may transmit, through communication network 126, the time of secondary phase zero crossing 122 (FIG. 2) to phase line identification system 130. Alternatively, each single phase electric meter 116 may transmit to an advanced metering infrastructure (AMI) 144. A person skilled in the art will readily recognize AMI 144 as a computerized system for collecting data (e.g., times of electrical usage, amounts of electrical usage, etc.) from a plurality of single phase electric meters 116. AMI 144, in turn, may transmit, through communication network 126, time of secondary phase zero crossing 122 for secondary phase line 114 to phase line identification system 130 (shown by dashed arrows).

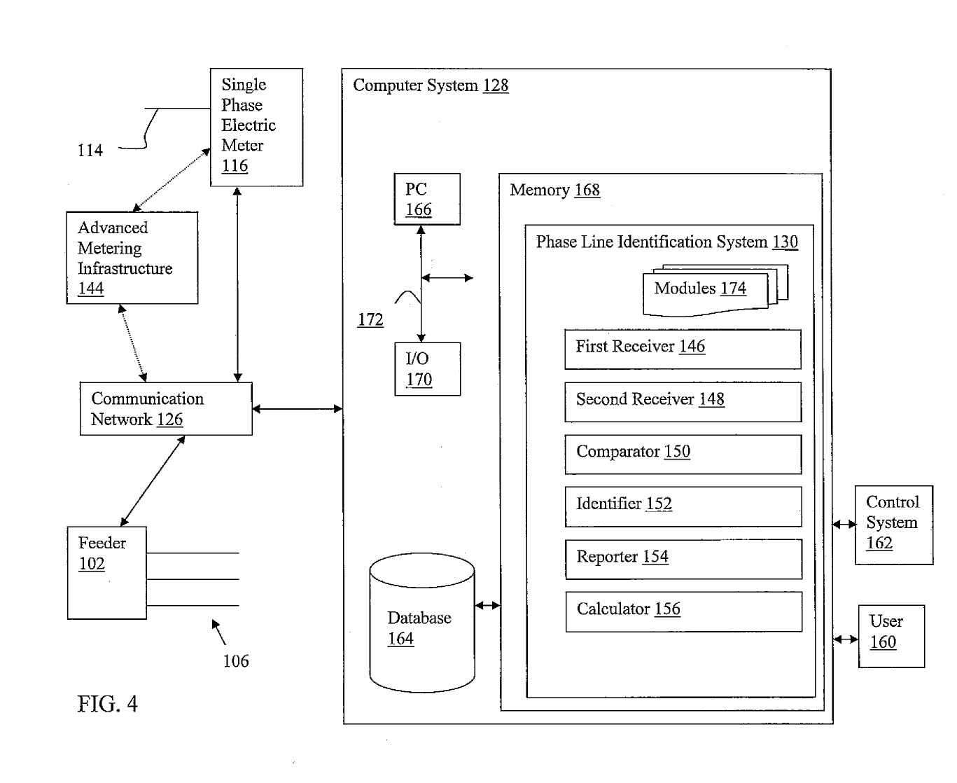

Computer system 128 may include phase line identification system 130, which makes computer system 128 operable to identify usage of primary phase lines 106. As indicated in FIG. 4, a first receiver 146, a second receiver 148, a comparator 150, an identifier 152, a reporter 154, and a calculator 156 may be optional components (or, modules) in phase line identification system 130. Alternatively, first receiver 146, second receiver 148, comparator 150, identifier 152, reporter 154, and calculator 156 may be part of an external system which may perform the functions described herein.

Computer system 128 is shown in communication with a user 160. A user 160 may be, for example, a programmer or operator. Additionally, computer system 128 is shown in communication with a control system 162. Control system 162 may be, for example, a computerized control system for controlling operation of feeder 102, AMI 144, or single phase electric meter 116. Computer system 128 is shown including a processing component 166 (e.g., one or more processors), a database 164, a memory 168, an input/output (I/O) component 170 (e.g., one or more I/O interfaces and/or devices), and a communications pathway 172. In one embodiment, processing component 166 executes program code, such as phase line identification system 130, which is at least partially embodied in memory 168. While executing program code, processing component 166 can process data, which can result in reading and/or writing the data to/from database 164, memory 168 and/or I/O component 170 for further processing. Communications pathway 172 provides a communications link between each of the components in computer system 128. I/O component 170 can comprise one or more human I/O devices or storage devices, which enable user 160 and/or control system 162 to interact with computer system 128 and/or one or more communications devices to enable user 160 and/or control system 162 to communicate with computer system 128 using any type of communications link. To this extent, phase line identification system 130 can manage a set of interfaces (e.g., graphical user interface(s), application program interface, and/or the like) that enable human and/or system interaction with phase line identification system 130.

Computer system 128 can comprise one or more general purpose computing articles of manufacture (e.g., computing devices) capable of executing program code installed thereon. As used herein, it is understood that “program code” means any collection of instructions, in any language, code or notation, that cause a computing device having an information processing capability to perform a particular function either directly or after any combination of the following: (a) conversion to another language, code or notation; (b) reproduction in a different material form; and/or (c) decompression. To this extent, phase line identification system 130 can be embodied as any combination of system software and/or application software. In any event, the technical effect of computer system 128 is to determine the identity of each primary phase line 106 tapped by each secondary phase line 114.

Further, phase line identification system 130 can be implemented using a set of modules 174. In this case, a module 174 can enable computer system 128 to perform a set of tasks used by phase line identification system 130, and can be separately developed and/or implemented apart from other portions of phase line identification system 130. Phase line identification system 130 may include modules 174 which comprise a specific use machine/hardware and/or software. Regardless, it is understood that two or more modules, and/or systems may share some/all of their respective hardware and/or software. Further, it is understood that some of the functionality discussed herein may not be implemented or additional functionality may be included as part of computer system 128.

When computer system 128 comprises multiple computing devices, each computing device may have only a portion of phase line identification system 130 embodied thereon (e.g., one or more modules 174). However, it is understood that computer system 128 and phase line identification system 130 are only representative of various possible equivalent computer systems that may perform a process described herein. To this extent, in other embodiments, the functionality provided by computer system 128 and phase line identification system 130 can be at least partially implemented by one or more computing devices that include any combination of general and/or specific purpose hardware with or without program code. In each embodiment, the hardware and program code, if included, can be created using standard engineering and programming techniques, respectively.

Regardless, when computer system 128 includes multiple computing devices, the computing devices can communicate over any type of communications link. Further, while performing a process described herein, computer system 128 can communicate with one or more other computer systems using any type of communications link. In either case, the communications link can comprise any combination of various types of wired and/or wireless links; comprise any combination of one or more types of networks; and/or utilize any combination of various types of transmission techniques and protocols.

As discussed herein, phase line identification system 130 enables computer system 128 to identify usage of primary phase lines 106. Phase line identification system 130 may include logic, which may include the following functions: receiving, comparing, identifying, reporting, calculating, and determining. In one embodiment, phase line identification system 130 may include logic to perform the herein-stated functions. Structurally, the logic may take any of a variety of forms such as a field programmable gate array (FPGA), a microprocessor, a digital signal processor, an application specific integrated circuit (ASIC) or any other specific use machine structure capable of carrying out the functions described herein. Logic may take any of a variety of forms, such as software and/or hardware. However, for illustrative purposes, phase line identification system 130 and logic included therein will be described herein as a specific use machine. As will be understood from the description, while logic is illustrated as including each of the above-stated functions, not all of the functions are necessary according to the teachings of the invention as recited in the appended claims.

In one embodiment, the invention provides a computer program embodied in at least one computer-readable storage medium, which when executed, enables a computer system (e.g., computer system 128) to identify usage by primary phase lines 106. To this extent, the computer-readable storage medium includes program code, such as phase line identification system 130, which implements some or all of a process described herein. It is understood that the term “computer-readable storage medium” comprises one or more of any type of tangible medium of expression capable of embodying a copy of the program code (e.g., a physical embodiment). For example, the computer-readable storage medium can comprise: one or more portable storage articles of manufacture; one or more memory/storage components of a computing device; paper; and/or the like. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

In another embodiment, the invention provides a method of providing a copy of program code, such as phase line identification system 130, which implements some or all of a process described herein. In this case, a computer system can generate and transmit, for reception at a second, distinct location, a set of data signals that has one or more of its characteristics set and/or changed in such a manner as to encode a copy of the program code in the set of data signals. Similarly, an embodiment of the invention provides a method of acquiring a copy of program code that implements some or all of a process described herein, which includes a computer system receiving the set of data signals described herein, and translating the set of data signals into a copy of the computer program embodied in at least one computer-readable medium. In either case, the set of data signals can be transmitted/received using any type of communications link.

In still another embodiment, the invention provides a method of generating a system for identify usage by primary phase lines 106. In this case, a computer system, such as computer system 128, can be obtained (e.g., created, maintained, made available, etc.) and one or more modules for performing a process described herein can be obtained (e.g., created, purchased, used, modified, etc.) and deployed to the computer system. To this extent, the deployment can comprise one or more of: (1) installing program code on a computing device from a computer-readable medium; (2) adding one or more computing and/or I/O devices to the computer system; and (3) incorporating and/or modifying the computer system to enable it to perform a process described herein.

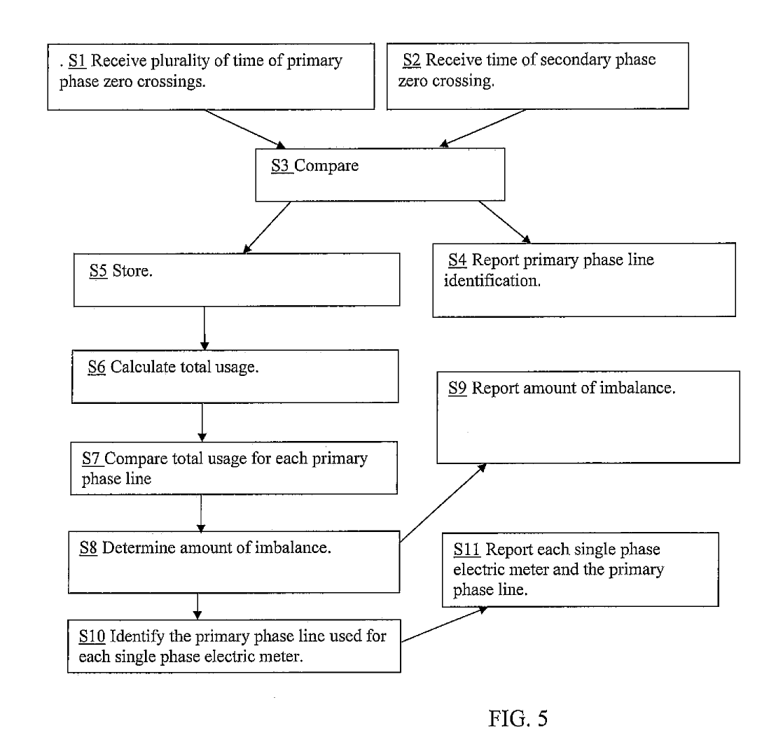

Returning to FIG. 4, a block diagram depicting an illustrative phase line identification system 130 in accordance with one embodiment of the invention is shown. Also referring to FIG. 5, a flow diagram representing an embodiment of a method of phase identification is illustrated. At steps S1 and S2, phase line identification system 130 may include a first receiver 146 receives a plurality of times of the primary phase zero crossing 118 for a plurality of primary phase lines 106 at feeder 102 and second receiver 148 receives time of secondary phase zero crossing 122 for secondary phase line 114 at single phase electric meter 116.

At step S3, comparator 150 identifies which of plurality of primary phase lines 106 feeds the secondary phase line 114 by comparing plurality of time of primary phase zero crossing 118 for plurality of primary phase lines 106 at feeder 102 to time of secondary phase zero crossing 122 for secondary phase line 114 at single phase electric meter 116. In this fashion, comparator 150 determines which one of plurality of primary phase lines 106 feeds the secondary phase line 114. That is, since secondary phase line 114 receives electricity from one of plurality of primary phase lines 106 and electricity travels at approximately the velocity of light, the matching of one time of primary phase zero crossing 120 matches with the time of secondary phase zero crossing 122 identifying primary phase line 106 tapped by secondary phase line 114. At step S4, reporter 154 may report the primary phase line identification for single phase electric meter 116 to a user 160 and/or control system 162.

At step S5, computer system 128 may store a plurality of primary phase line identifications for each of plurality of single phase electric meters 116, e.g., in database 164. At step S6, calculator 156 may calculate a total usage for each primary phase line 106. Calculating total usage for each primary phase line 106 may include summing the number of primary phase line identifications for each primary phase line 106.

Having stored a plurality of primary phase line identifications for each of plurality of primary phase lines, at step S7, comparator 150 may further compare total usage for each primary phase line 106 with total usage of the plurality of primary phase lines 106. At step S8, comparator 150 may also determine an amount of imbalance between total usage for each primary phase line 106 and total usage of plurality of primary phase lines 106. At step S9, reporter 154 may further report amount of imbalance between total usage for each primary phase line 106 and total usage of plurality of primary phase lines 106 to user 160 and/or control system 162 allowing user 160 and/or control system to respond to amount of imbalance as previously described.

Further, at step S10, identifier 152 may identify primary phase line 106 used for each single phase electric meter 116 and, at step S11, reporter 154 may further report each single phase electric meter 116 and primary phase line 106 being used by each single phase electric meter 116 to user 160 and/or control system 162.

User 160 and/or control system 162 may receive results of comparing, identifying, and determining from reporter 154. User 160 and/or control system 162 may interact with computer system 128, AMI 152, feeder 102, and/or single phase electric meter 116 in response to receiving results.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A phase line identification system, comprising:
at least one computer hardware device including:
a first receiver that receives a plurality of times of a primary phase zero crossing for a plurality of primary phase lines at a feeder;
a second receiver that receives a time of a secondary phase zero crossing for a secondary phase line at a single phase electric meter;
a comparator that identifies which of the plurality of primary phase lines feeds the secondary phase line by comparing the plurality of times of the primary phase zero crossing for the plurality of primary phase lines at the feeder to the time of the secondary phase zero crossing of the secondary phase line at the single phase electric meter to determine which one of the plurality of times of the primary phase zero crossing matches the time of the secondary phase zero crossing.

2. The system of claim 1, further comprising:
a reporter that reports a primary phase line identification for a single phase electric meter to a user.

3. The system of claim 2, further comprising:
a database that stores a plurality of primary phase line identifications for each of a plurality of single phase electric meters; and
a calculator that calculates a total usage for each primary phase line.

4. The system of claim 3, wherein the comparator further compares the total usage for each primary phase line; and determines an amount of imbalance between the total usage for each primary phase line.

5. The system of claim 4, wherein the reporter further reports the amount of imbalance between the total usage for each primary phase line to the user.

6. The system of claim 5, wherein the comparator further identifies the primary phase line used for each single phase electric meter.

7. The system of claim 6, wherein the reporter further reports each single phase electric meter and the primary phase line being used by each single phase electric meter to the user.

8. A method, comprising:
receiving a plurality of time of a primary phase zero crossing for a plurality of primary phase lines at a feeder;
receiving a time of a secondary phase zero crossing for a secondary phase line at a single phase electric meter;
identifying which of the plurality of primary phase lines feeds the secondary phase line by comparing the plurality of times of the primary phase zero crossing for the plurality of primary phase lines at the feeder to the time of the secondary phase zero crossing of the secondary phase line at the single phase electric meter to determine which one of the plurality of times of the primary phase zero crossing matches the time of the secondary phase zero crossing.

9. The method of claim 8, further comprising:
reporting a primary phase line identification for the single phase electric meter to a user.

10. The method of claim 9, further comprising:
storing a plurality of primary phase line identifications for each of a plurality of single phase electric meters; and
calculating a total usage for each primary phase line.

11. The method of claim 10, further comprising:
comparing the total usage for each primary phase line; and
determining an amount of imbalance between the total usage for each primary phase line.

12. The method of claim 11, further comprising:
reporting the amount of imbalance between the total usage for each primary phase line to the user.

13. The method of claim 12, further comprising:
identifying the primary phase line used for each single phase electric meter.

14. The method of claim 13, further comprising:
reporting each single phase electric meter and the primary phase line being used by each single phase electric meter to the user.

15. A computer program product comprising program code embodied in at least one computer-readable storage medium, which when executed, enables a computer system to implement a method, the method comprising:
receiving a plurality of time of a primary phase zero crossing for a plurality of primary phase lines at a feeder;
receiving a time of a secondary phase zero crossing for a secondary phase line at a single phase electric meter;
identifying which of the plurality of primary phase lines feeds the secondary phase line by comparing the plurality of times of the primary phase zero crossing for the plurality of primary phase lines at the feeder to the time of the secondary phase zero crossing of the secondary phase line at the single phase electric meter to determine which one of the plurality of times of the primary phase zero crossing matches the time of the secondary phase zero crossing.

16. The computer program product of claim 15, further comprising:
reporting the primary phase line identification for the single phase electric meter to a user.

17. The computer program product of claim 16, further comprising:
storing a plurality of primary phase line identifications for each of a plurality of single phase electric meters; and
calculating a total usage for each primary phase line.

18. The computer program product of claim 17, further comprising:
comparing the total usage for each primary phase line; and
determining an amount of imbalance between the total usage for each primary phase line.

19. The computer program product of claim 18, further comprising:
reporting the amount of imbalance between the total usage for each primary phase line to the user.

20. The computer program product of claim 19, further comprising:
identifying the primary phase line used for each single phase electric meter; and
reporting each single phase electric meter and the primary phase line being used by each single phase electric meter to the user.
